(19) United States
(12) Patent Application Publication
(10) Pub. No.: US 2025/0244674 A1
(43) Pub. Date: Jul. 31, 2025

(54) METHOD FOR IMAGING A MASK LAYER AND ASSOCIATED IMAGING SYSTEM

(71) Applicant: XSYS PREPRESS NV, Ieper (BE)

(72) Inventors: Frederik DEFOUR, Boezinge (BE); Dirk Ludo Julien DE RAUW, Ninove (BE)

(73) Assignee: XSYS PREPRESS NV, Ieper (BE)

(21) Appl. No.: 18/854,630

(22) PCT Filed: Apr. 4, 2023
(86) PCT No.: PCT/EP2023/058856

§ 371 Date: Oct. 7, 2024

(30) Foreign Application Priority Data
Apr. 8, 2022 (NL) 2031541

(51) Int. Cl. G03F 7/20; G03F 7/00; G03F 7/24

(52) U.S. Cl. CPC G03F 7/202; G03F 7/24; G03F 7/7055

(57) ABSTRACT

A method for imaging a mask layer includes reading imaging data for a sequence of at least (C1+C2) pixels, at a first moment, using a group of C1 first imaging beams for imaging substantially simultaneously a first group of C1 pixels of said sequence in accordance with the imaging data, at a second moment, using a group of C2 second imaging beams for imaging substantially simultaneously a second group of C2 pixels of said sequence in accordance with the imaging data, repeating the reading of imaging data, the using of a group of C1 first imaging beams for imaging at a first moment, and the using of a group of C2 second imaging beams for imaging at a second moment for a next sequence of at least (C1+C2) pixels.

### FIELD OF THE INVENTION

The field of the invention relates to imaging a mask layer in the field of printing technology. Various embodiments in this document relate to methods for imaging a mask layer, control modules, and computer programs for use in imaging a mask layer, and to methods and systems for imaging and exposing a relief precursor.

### DESCRIPTION OF RELATED ART

In known methods for imaging a mask layer imaging data provides information on pixels. Imaging beams then ablate the mask layer based on this information on pixels. Given the complexity of pixels spots on the mask layer are sometimes ablated individually. This is a time-consuming process.

In addition, during the imaging of the mask layer it is necessary to translate what is in the imaging data into the setting of the beams. The correspondence between the imaging data and the beam settings may be found for example at each time after the imaging data is provided. This is however computationally intensive.

Furthermore, there is often a need to image a mask layer under multiple settings to produce different areas on the mask layer. This can mean for example providing multiple separate series of imaging data for the same mask layer. These different series of imaging data must be interpreted separately by the control module before they can be used to instruct beams to ablate spots on the mask layer.

### SUMMARY OF THE INVENTION

Some embodiments of the present disclosure relate to a method which can image a mask layer more efficiently while keeping the precision of the ablation. Some embodiments of the present disclosure relate to a method which can simplify the translation of the imaging data into the instructions to the beams. Some embodiments of the present disclosure relate to a method which allows the imaging data to control the beams under multiple settings while reducing the complexity of translating the imaging data into ablation instructions.

According to a first aspect of the disclosure is a method for imaging a mask layer, comprising the steps:
providing a mask layer,
reading imaging data for a sequence of at least (C1+C2) pixels, C1 and C2 being integers greater than or equal to 1,
at a first moment in time, using a group of Cl first imaging beams for imaging substantially simultaneously a first group of Cl pixels of said sequence in accordance with the read imaging data,
at a second moment in time, using a group of C2 second imaging beams for imaging substantially simultaneously a second group of C2 pixels of said sequence in accordance with the read imaging data,
optionally, at one or more subsequent moments in time, using a subsequent group of imaging beams for imaging substantially simultaneously a subsequent group of pixels in accordance with the read imaging data, said pixels of said subsequent group being different from the pixels of the first and second group,
repeating the reading of imaging data, the using of a group of CI first imaging beams for imaging at a first moment in time, the using of a group of C2 second imaging beams for imaging at a second moment in time, and optionally the using of a subsequent group of imaging beams for imaging at one or more subsequent moments in time, for a next sequence of at least (C1+C2) pixels.

Thus, a plurality of at least (C1+C2) distinct imaging beams is arranged next to each other, and comprises a first group of Cl imaging beams (L1) and a second groups of C2 imaging beams (L2). The imaging beams are distinct in the sense that none of the beams of the first group overlaps or corresponds with a beam of the second group. Thanks to organising the pixels into at least two groups and using groups of beams to image pixels, a compromise between the speed of printing and the accuracy can be reached.

The first aspect of the disclosure may comprise any one of, or any technically possible combinations of the following features:
C1 and C2 are integers greater than or equal to 2, and wherein said C1 pixels of the first group are selected such that at least two pixels of the first group are separated by at least one pixel not belonging to the first group and said C2 pixels of the second group are selected such that at least two pixels of the second group are separated by at least one pixel not belonging to the second group.

Under this embodiment a significant number of pixels can be imaged at the same time. The process of imaging a mask layer is therefore simplified and accelerated. In addition, by separating at least two pixels in the first group and at least two pixels in the second group by the pixel(s) not belonging to the respective group, interference amongst the pixels of a group can be reduced, and the imaging is easier to control.
C1=C2=C, and wherein each sequence contains N*C pixels, N being an integer greater than or equal to 2.

Having the same number of pixels in each group simplifies the process of imaging the mask layer.
the method further comprises providing a clock having a first frequency f1, wherein a time period between subsequent moments in time corresponds to 1/f1, and wherein reading imaging data of the at least (C1+C2) pixels comprises reading imaging data of the Cl pixels and then, after an interval of 1/f1, reading imaging data of the C2 pixels.

In this particular embodiment each group of pixels is read in turn: as a first step the first group of pixels are read, and later as a second step the second group of pixels are read.
the C pixels in the n-th group, n being an integer, 1≤n≤N, comprise the n-th pixel, the (n+N)-th pixel, the (n+2*N)-th pixel, etc. of the sequence of N*C pixels.

Under this particular embodiment the pixels in the n-th group are evenly spaced. This regular interval makes it more straightforward to read the corresponding imaging data, and/or imaging a group of pixels.
the sequence corresponds to a single row in the imaging data, or the sequence corresponds to parts of different rows in the imaging data, preferably the C pixels in the n-th group comprises the n-th pixel of the m-th row, the (n+N)-th pixel of the (m+1)-th row, the (n+2*N)-th pixel of the (m+2)-th row, . . . , 1≤m≤N with m being an integer.

When the sequence corresponds to a single row in the imaging data reading the first and the second group of pixels is easy to implement. When the sequence corresponds to difference rows in the imaging data it is possible to compensate the movement of the mask layer when different groups of pixels are imaged, so that the pixels belonging to different rows can nevertheless be imaged on a straight line, in particular on a line perpendicular to the movement direction of the mask layer.
the method comprises obtaining a first set of imaging settings for said first group of Cl pixels and imaging substantially simultaneously the first group of Cl pixels in accordance with said first set of imaging settings, and obtaining a second set of imaging settings for said second group of C2 pixels and imaging substantially simultaneously the second group of C2 pixels in accordance with said second set of imaging settings, wherein for each group of pixels the set of imaging settings is different.

With a different imaging setting for each group of pixels, different imaging results can be obtained for each group of pixels distinct from other groups of pixels.
the method comprises obtaining the first or the second set of imaging settings comprises seeking an imaging setting in a look-up table based on a set of bit values of the image data corresponding to the pixels of the first or second group, respectively.

By using a look-up table, the correspondence between the imaging data and the settings of the beams can be determined and fixed before a mask a layer is imaged. When imaging the pixels it would therefore only be necessary to refer to the look-up table without any additional calculations.
the set of bit values comprises for every pixel either ‘1’ if the pixel is an imaging pixel, or ‘0’ if the pixel is a non-imaging pixel.
the set of bit values comprises two or more bit values for every pixel.

By having two or more bit values for every pixel, more possible settings are available for each pixel in an image file. A greater variety of imaged pixels can therefore be obtained from one single image file.
the first and second set of imaging settings comprises CI imaging settings for the Cl first imaging beams and C2 imaging settings for the C2 second imaging beams, respectively.
each set of imaging settings specifies a value which is representative for a size and/or shape and/or position of an imaged spot corresponding with an imaging pixel; wherein preferably the first and second sets of imaging settings define any one or more of the following parameters:
   an intensity value to be used for generating an imaged feature corresponding with an imaging pixel, e.g. an intensity value for controlling a beam used for the imaging,
   a time interval to be used for generating an imaged feature corresponding with an imaging pixel, e.g. an on-time value for controlling a beam used for the imaging,
   a beam diameter value and/or beam shape value for controlling a beam used for the imaging,
   a number of passes used for the imaging,
   an indication of an exposure head of a plurality of exposure heads to be used for generating an imaged feature or a group of imaged features corresponding to a pixel or a group of pixels for the imaging.
all the pixels in the first group are separated by at least one pixel not belonging to the first group and wherein all the pixels in the second group are separated by at least one pixel not belonging to the second group.

Because all the pixels in the first and second groups are separated by the pixels not belonging to the respective group, interference between the pixels in each group is further reduced.
the mask layer is being moved in a movement direction (M) relative to the imaging beams whilst the first group of Cl pixels and the second group of C2 pixels, and the subsequent group of pixels if present, are imaged.

Under this embodiment it is possible to image pixels of different groups placed next to others in the movement direction without interruption.
the mask layer is rotating on a drum whilst the first group of Cl pixels and the second group of C2 pixels, and the subsequent group of pixels if present, are imaged, and the movement direction (M) corresponds to a rotational direction of the drum. This will typically be the case for an external drum configuration where a mask layer is wrapped around an external surface of the drum.
the mask layer is moving on a flatbed table and/or the imaging beams are moving along a flatbed table whilst the first group of Cl pixels and the second group of C2 pixels, and the subsequent group of pixels if present, are imaged, and the movement direction (M) corresponds to a longitudinal direction of the flatbed table.
the mask layer is placed on an internal surface of a drum, the mask layer rotating relative to the imaging beams whilst the first group of Cl pixels and the second group of C2 pixels, and the subsequent group of pixels if present, are imaged, and the movement direction (M) corresponds to a rotational direction of the mask layer or the imaging beams. This will typically be the case for an internal drum configuration where a mask layer is placed on an internal surface of the drum.

These three embodiments each corresponds to a particular situation: one when the mask layer is wrapped on an external surface of the drum, another when the mask layer is placed on the flatbed table, and a third where the mask layer is placed on an internal surface of a drum.
the first and the second groups of imaging beams, and the subsequent group of imaging beams if present, are arranged next to each other and aligned along a line when the groups of imaging beams are observed perpendicularly to the mask layer, said line defining an angle with a transverse direction (T) perpendicular to the movement direction (M), the angle compensating for the movement of the mask layer between the first and the second moment in time.

Thanks to this arrangement, even when the mask layer moves in the movement direction it is possible to image pixels aligned in the transverse direction perpendicular to the movement direction without any additional adjustments due to the movement in the movement direction.
the method further comprising moving the imaging beams relative to the mask layer in a transverse direction (T) perpendicular to the movement direction so that the imaging beams move relative to the mask layer over at least (C1+C2) pixels in the transverse direction.

This embodiment makes it possible to image additional pixels next to the (C1+C2) pixels in the transverse direction of the drum and/or of the flatbed table.
the moving in the transverse direction (T) perpendicular to the movement direction (M) is substantially continuous.

The continuous movement in the transverse direction makes it possible to image additional pixels next to the (C1+C2) pixels in the transverse direction without any interruption.

According to a second aspect of the disclosure is method for imaging a mask layer, comprising the steps:
providing a mask layer,
providing a look-up table with a plurality of imaging settings in function of bit sequences,
reading imaging data for a plurality of pixels;
obtaining an imaging setting from the look-up table based on a bit sequence of the imaging data corresponding to the plurality of pixels;
using a plurality of imaging beams for imaging substantially simultaneously the plurality of pixels in accordance with the obtained imaging setting.

Thanks to this method it is possible to find the correspondence between the imaging data and the instructions to the beams simply in a look-up table without carrying any additional calculation. The process of imaging a mask layer is therefore much simplified.

The second aspect of the disclosure may comprise any one of, or any technically possible combinations of the following features:
the set of bit values comprises for every pixel a ‘I’ if the pixel is an imaging pixel, or a ‘0’ if the pixel is a non-imaging pixel.
the set of bit values comprises two bit values for every pixel.

By having two bit values for every pixel it is possible to obtain multiple settings of the imaging beams based on one single image file.
the imaging setting comprises a plurality of separate independent values for the plurality imaging beams.

Under this embodiment each imaging beam is capable of imaging pixels independently of other imaging beams.
each imaging setting specifies a value which is representative for a size and/or shape and/or position of an imaged spot corresponding with an imaging pixel; wherein preferably the imaging setting defines any one or more of the following parameters:
   an intensity value to be used for generating an imaged feature corresponding with an imaging pixel, e.g. an intensity value for controlling a beam used for the imaging,
   a time interval to be used for generating an imaged feature corresponding with an imaging pixel, e.g. an on-time value for controlling a beam used for the imaging,
   a beam diameter value and/or beam shape value for controlling a beam used for the imaging,
   a number of passes used for the imaging,
   an indication of an exposure head of a plurality of exposure heads to be used for generating an imaged feature or a group of imaged features corresponding to a pixel or a group of pixels for the imaging.
reading imaging data comprises reading imaging data for a sequence of at least (C1+C2) pixels, C1 and C2 being integers greater than or equal to 1, wherein obtaining the imaging setting comprises obtaining a first imaging setting based on a plurality of first bit values corresponding to C1 pixels of the sequence; and a second imaging setting based on a plurality of second bit values corresponding to C2 pixels of the sequence; and wherein using a plurality of imaging beams for imaging comprises:
at a first moment in time, using a group of Cl first imaging beams for imaging substantially simultaneously a first group of Cl pixels of said sequence in accordance with the first imaging setting;
at a second moment in time, using a group of C2 second imaging beams for imaging substantially simultaneously a second group of C2 pixels of said sequence in accordance with the second imaging setting;
optionally, at one or more subsequent moments in time, using a subsequent group of imaging beams for imaging substantially simultaneously a subsequent group of pixels in accordance with the read imaging data, said pixels of said subsequent group being different from the pixels of the first and second group;
the method further comprising repeating reading imaging data, obtaining an imaging setting from the look-up table, and using a plurality of imaging beams for imaging for a next sequence of at least (C1+C2) pixels.
C1 and C2 are integers greater than or equal to 2; and wherein said C1 pixels of the first group are selected such that at least two pixels of the first group are separated by at least one pixel not belonging to the first group and said C2 pixels of the second group are selected such that at least two pixels of the second group are separated by at least one pixel not belonging to the second group.
C1=C2=C, wherein each sequence contains N*C pixels, N being an integer greater than or equal to 2.
the C pixels in the n-th group, n being an integer, 1≤n≤N, comprise the n-th pixel, the (n+N)-th pixel, etc. of the sequence of N*C pixels.
the sequence corresponds to a single row in the imaging data, or the sequence corresponds to parts of different rows in the imaging data, preferably the C pixels in the n-th group comprises the n-th pixel of the m-th row, the (n+N)-th pixel of the (m+1)-th row, the (n+2*N)-th pixel of the (m+2)-th row, . . . , 15 m≤N with m being an integer.

According to a third aspect of the disclosure is method for imaging a mask layer, comprising the steps:
providing a mask layer,
reading imaging data for a plurality of pixels;
obtaining an imaging setting based on a sequence of bit values comprising at least two bit values for every pixel of said plurality of pixels;
using a plurality of imaging beams for imaging substantially simultaneously the plurality of pixels in accordance with the obtained imaging setting.

By having at least two bit values for every pixel, one set of imaging data can control the imaging beams under at least two settings for each pixel. Consequently it is possible to obtain multiple variations of each pixel from one image file.

The third aspect of the disclosure may comprise any one of, or any technically possible combinations of the following features:
the imaging setting comprises a plurality of separate independent values for the plurality imaging beams.
each imaging setting specifies a value which is representative for a size and/or shape and/or position of an imaged spot corresponding with an imaging pixel; wherein preferably the imaging setting defines any one or more of the following parameters:
   an intensity value to be used for generating an imaged feature corresponding with an imaging pixel, e.g. an intensity value for controlling a beam used for the imaging,
   a time interval to be used for generating an imaged feature corresponding with an imaging pixel, e.g. an on-time value for controlling a beam used for the imaging,
   a beam diameter value and/or beam shape value for controlling a beam used for the imaging,
   a number of passes used for the imaging,
   an indication of an exposure head of a plurality of exposure heads to be used for generating an imaged feature or a group of imaged features corresponding to a pixel or a group of pixels for the imaging.

Some embodiments of the present disclosure relate to a method as described above, wherein the mask layer is provided on a photopolymerizable layer of a relief precursor and wherein, after the imaging, the photopolymerizable layer of the relief precursor is exposed through the mask layer and the relief precursor is developed to obtain a relief structure. The mask layer may be an integral part of the relief precursor or may be a separate item, which is attached to the relief precursor before the exposure to electromagnetic radiation.

Some embodiments of the present disclosure relate to a relief structure obtained by the method described above.

Some embodiments of the present disclosure relate to a computer program comprising computer-executable instructions to control an embodiment of the method as described above in relation to any one of the aspects of the disclosure, when the program is run on a computer.

Some embodiments of the present disclose relate to a digital data storage medium encoding a machine-executable program of instructions to perform any one of the steps of the method as described above in relation to any one of the aspects of the disclosure.

Some embodiments of the present disclose relate to a computer program product comprising computer-executable instructions for controlling or performing the method as described above in relation to any one of the above aspects of the disclosure, when the program is run on a computer.

Some embodiments of the present disclosure relate to a control module configured to carry out the method as described above in relation to any one of the above aspects of the disclosure.

Some embodiments of the present disclosure relate to a system for treating a relief precursor, comprising an imager configured to image a mask layer; and a digital data storage medium as described above and/or a control module as described above to control the imager. Optionally, the system further comprises any one or more of the following: at least one transport system configured to transport the relief precursor, a storage device, an exposure means configured to expose the relief precursor through the imaged mask layer, a developing means configured to remove at least a part of non-exposed material from the relief precursor, a drying system, a post-exposure device, a cutting device, a mounting station, a heater.

Another embodiment of the present disclosure relates to a mask layer obtained by the method described above.

Any feature of the first aspect of the present disclosure may be combined with any feature of the second and/or the third aspect of the present disclosure.

### BRIEF DESCRIPTION OF THE DRAWINGS

The above and further aspects of the disclosure will be explained in more detail below on the basis of a number of embodiments, which will be described with reference to the appended drawings. In the drawings:

FIG. 1 illustrates an example embodiment of a system for imaging a mask layer having two groups of pixels, with three pixels per group;

FIG. 2 explains the different steps at different moments in time during the imaging of the mask layer under an example embodiment;

FIG. 3 shows an example embodiment of a look-up table;

FIGS. 4-7 indicate the amplitude of the laser beams under four sequences of bit values comprising two bit values for every pixel, the two bit values having been converted into 1 bit values;

FIG. 8 illustrates another example embodiment of a system for imaging a mask layer having three groups of pixels with two pixels per group;

FIG. 9 illustrates a schematic view of an exemplary embodiment of a system for producing a relief structure.

### DESCRIPTION OF THE INVENTION

Flexographic printing or letterpress printing are techniques which are commonly used for high volume printing. Flexographic or letterpress printing plate are relief plates with printing elements, typically called reliefs or dots, protruding above non-printing elements in order to generate an image on a recording medium such as paper, cardboard, films, foils, laminates, etc. Also, cylindrically shaped printing plates or sleeves may be used.

Various methods exist for making flexographic or letterpress printing plate precursors. According to conventional methods flexographic or letterpress printing plate precursors are made from multilayer substrates comprising a backing layer and one or more photocurable layers (also called photosensitive layers). Those photocurable layers are cured by exposure to electromagnetic radiation through a mask layer containing the image information or by direct and selective exposure to electromagnetic radiation e.g. by scanning of the plate to transfer the image information in order to obtain a relief plate. After curing the uncured parts are removed either by using liquids that are able to dissolve or disperse the uncured material or by thermal treatment in which the uncured material is liquefied and removed. Removal of the liquefied material may be achieved by adhesion or adsorption to a developer material or by application beams of solids, liquids or gases which may be heated. An alternative is to remove the material in the non-printing area by ablation using high power laser beams.

In flexographic or letterpress printing, ink is transferred from a flexographic plate to a print medium. More in particular, the ink is transferred on the relief parts of the plate, i.e. in the halftone dots or solid reliefs, and not on the non-relief parts. During printing, the ink on the relief parts is transferred to the print medium. Greyscale images are typically created using half-toning, e.g. using a screening pattern, preferably an AM screening pattern. By greyscale is meant, for a plate printing in a particular colour, the amount of that colour being reproduced. For example, a printing plate may comprise different half-tone dot regions to print with different densities in those regions. In order to increase the amount of ink transferred and to increase the so-called ink density on the substrate, an additional very fine structure is applied to the surface of the printing dots, i.e. the relief areas. This fine surface structure is typically obtained by adding a fine high resolution sampling pattern to the image file, so that it is then transferred to the corresponding mask used for exposure.

Images reproduced by printing plates typically include both solid image areas and a variety of grey tone areas, also called halftone areas. A solid area corresponds with a single relief in the printing plate which is completely covered by ink so as to produce the highest density on a print material. A grey tone or halftone area corresponds with an area with multiple printing dots at a distance of each other, i.e. an area where the appearance of the printed image is of a density intermediate between pure white (total absence of ink) and pure colour (completely covered by ink). Grey areas are produced by the process of half-toning, wherein a plurality of relief elements per unit area is used to produce the illusion of different density printing. These relief elements are commonly referred to in the printing industry as ‘halftone dots’. Image presentation is achieved by changing a percentage of area coverage (dot intensity) from region to region. Dot intensity may be altered by altering the dot size (AM screening) and/or the dot density, i.e. the dot frequency (FM screening).

In a flexographic or letterpress plate, the halftone dots are relief areas having their surface at the top surface of the plate. The plate in the area surrounding the dot has been etched to a depth which reaches to a floor. The height of a halftone dot is the distance of the surface of the dot (and of the plate surface) to the floor. The halftone relief is the relief extending from the floor to the top surface.

In the present method for imaging a mask layer, first of all a mask layer is provided. This provided mask layer is for example is a blank mask layer without any imaged pixels. The mask layer may be arranged on a support layer and may be attached to the relief precursor before exposure to electromagnetic radiation for curing. The mask layer may be an integral part of a relief precursor and may represent the outer surface of the precursor during imaging.

Next, imaging data for a sequence of at least C1+C2 pixels is read. The imaging data for example comes from an image file. C1 and C2 are integers greater than or equal to 1.

According to one embodiment C1 and C2 are integers greater than or equal to 2. Under this embodiment, it is preferable that said C1 pixels of the first group are selected such that at least two pixels of the first group are separated by at least one pixel not belonging to the first group, and/or said C2 pixels of the second group are selected such that at least two pixels of the second group are separated by at least one pixel not belonging to the second group. The distance between two pixels in a group is for example around 30 microns. According to a preferred embodiment all the pixels in the first group are separated by at least one pixel not belonging to the first group, and/or all the pixels in the second group are separated by at least one pixel not belonging to the second group.

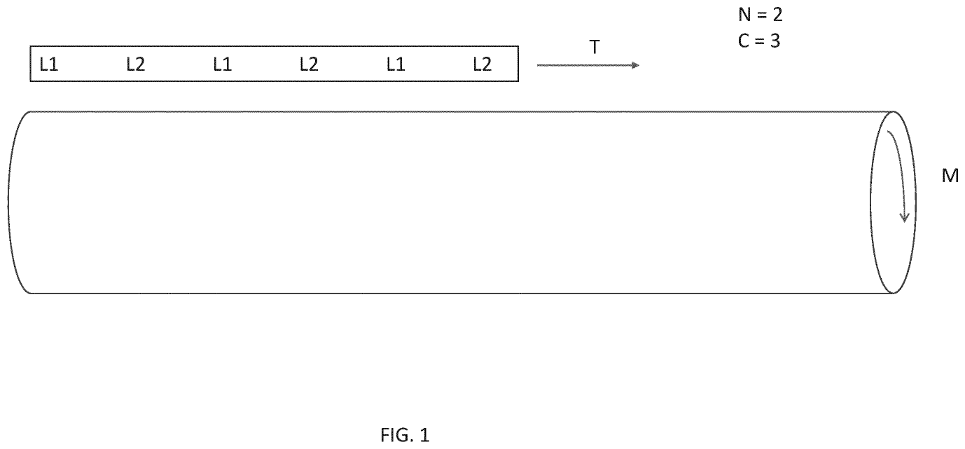

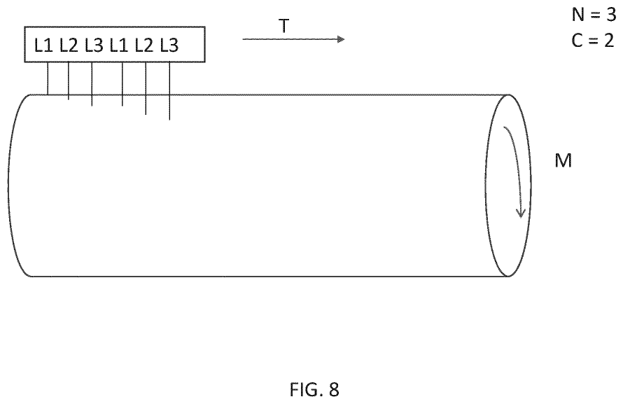

According to some embodiments, C1=C2=C. Each sequence contains N*C pixels, N being an integer greater than or equal to 2. N represents the number of groups in this description that follows. In the embodiment illustrated on FIG. 1, C1=C2=3, and N=2. This means that there are two groups of pixels, with three pixels per group. In the embodiment illustrated on FIG. 8, C1=C2=2, and N=3. This means that there are three groups of pixels, with two pixels per group.

At a first moment in time, a group of Cl first imaging beams L1 is used for imaging substantially simultaneously a first group of Cl pixels in the sequence of C1+C2 pixels in accordance with the read imaging data.

At a second moment in time, a group of C2 second imaging beams L2 is used for imaging substantially simultaneously a second group of C2 pixels in the sequence of C1+C2 pixels in accordance with the read imaging data.

According to some embodiments the imaging data for the first group of Cl pixels is read and the first group of Cl pixels is imaged before the imaging data for the second group of C2 pixels is read and the second group of C2 pixels is imaged.

As an alternative the imaging data for the first and the second group of (C1+C2) pixels is read before the first group of Cl pixels is imaged and/or the second group of C2 pixels is imaged.

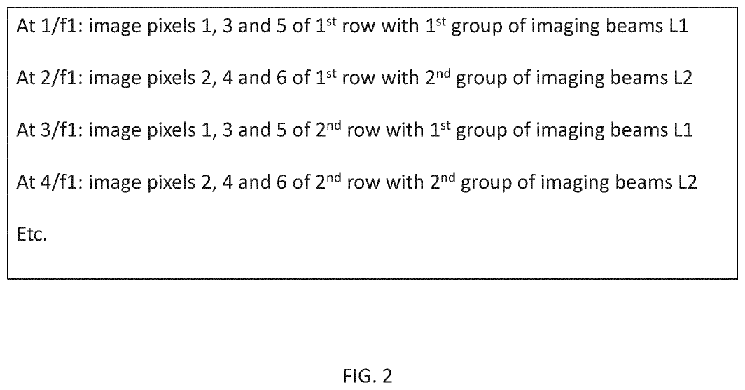

According to some embodiments a clock having a first frequency f1 is provided. The time period between subsequent moments in time corresponds to 1/f1. According to these embodiments when imaging data of the at least (C1+C2) pixels is read, first the imaging data of the Cl pixels is read (and optionally the Cl pixels are imaged), for example at the moment of 1/f1, as shown in FIG. 2.

Then, after an interval of 1/f1, for example at the moment of 2/f1 under the example in FIG. 2, imaging data of the C2 pixels is read (and optionally the C2 pixels are imaged).

According to some embodiments the C pixels in the n-th group, n being an integer, 1≤n≤N, comprise the n-th pixel, the (n+N)-th pixel, the (n+2*N)-th pixel, etc. of the sequence of N*C pixels. Under the example in FIGS. 1 and 2, the first group of three pixels comprises the first, the third, and the fifth pixels in the sequence of six pixels. The second group of three pixels comprises the second, the fourth, and the sixth pixels in the sequence of six pixels.

According to some embodiments, such as the one illustrated in FIG. 1, the sequence corresponds to a single row in the imaging data. Under these embodiments, after the groups of pixels in the first row are imaged, the method moves to imaging the second row of pixels. As shown in FIG. 2, still with the examples of two groups of pixels with three pixels per group (N=2; C=3), at one moment, for example at 3/f1, the first, third, and the fifth pixels of the second row are imaged with the first group of imaging beams L1. At another later moment, for example at 4/f1, the second, the fourth, and sixth pixels of the second row are imaged with the second group of imaging beams L2.

According to some other embodiments not illustrated in the figures, the sequence corresponds to parts of different rows in the imaging data. According to a preferred implementation under this embodiment the C pixels in the n-th group comprises the n-th pixel of the m-th row, the (n+N)-th pixel of the (m+1)-th row, the (n+2*N)-th pixel of the (m+2)-th row, . . . , 15 m≤N with m being an integer. Again using the example in FIG. 1 where N=2 and C=3, the pixels in the first group comprises the first pixel in the first row, the third pixel in the second row, and the fifth pixel in the third row. The pixels in the second group comprises the second pixel in the first row, the fourth pixel in second row, and the sixth pixel in the third row. Using the example in FIG. 8 where N=3 and C=2, the pixels in the first group comprises the first pixel in the first row and the fourth pixel in the second row, the pixels in the second group comprises the second pixel in the first row and fifth pixel in the second row, and pixels in the third group comprises the third pixel in the first row and sixth pixel in the second row.

According to some optional embodiments, at one or more subsequent moments in time, a subsequent group of imaging beams L3 is used for imaging substantially simultaneously a subsequent group of pixels in accordance with the read imaging data. The pixels of the subsequent group are different from the pixels of the first and second group. In the embodiment illustrated in FIG. 8, at a subsequent moment in time, for example at the moment of 3/f1, a third group of imaging beams L3 is used for imaging substantially simultaneously a third group of pixels.

According to some embodiments the method comprises obtaining a first set of imaging settings for the first group of Cl pixels and imaging substantially simultaneously the first group of Cl pixels in accordance with the first set of imaging settings. The obtaining of the first set of imaging settings is for example carried out between the reading of imaging data of all groups of pixels and the imaging of the first group of Cl pixels. According to some embodiments the method comprises obtaining a second set of imaging settings for the second group of C2 pixels and imaging substantially simultaneously the second group of C2 pixels in accordance with the second set of imaging settings. The obtaining of the second set of imaging settings is for example carried out between the reading of imaging data of all groups of pixels and the imaging of the second group of C2 pixels. As an alternative, the obtaining of the first and second sets of imaging settings is carried out before the imaging of the first group of Cl pixels and before the imaging of the second group of C2 pixels.

According to some embodiments the obtaining of all sets of imaging settings is carried out before the imaging of any pixels or any group of pixels. According to some embodiments the set of imaging settings for at least two groups of pixels is different. According to some embodiments the set of imaging settings for each group of pixels is different.

Optionally the method comprises obtaining a subsequent set of imaging settings for the subsequent group of pixels and imaging substantially simultaneously the subsequent group of pixels in accordance with the subsequent set of imaging settings. This is for example carried out between the reading of imaging data of all groups of pixels and the imaging of the subsequent group of pixels.

According to some embodiments the obtaining of the first or the second set of imaging settings comprises seeking an imaging setting in a look-up table based on a set of bit values of the image data corresponding to the pixels of the first or the second group, respectively. Details on how to look for an imaging setting in a look-up table will be explained in more detail below.

According to some embodiments the mask layer is being moved in a movement direction M relative to the imaging beams L1, L2, L3 whilst the first group of Cl pixels and the second group of C2 pixels, and the subsequent group of pixels if present, are imaged. This cam mean that mask layer moves as the imaging beams L1, L2, L3 remain stationary. This can mean that the image beans L1, L2, L3 moves while the mask layer remains stationary. This can also mean that both the mask layer and the imaging beams L1, L2, L3 move with one having a relative movement with regard to the other.

There are three preferred embodiments when the mask layer is moved in the movement direction M. The first preferred embodiment is when the mask layer is rotating on a drum. Under this preferred embodiment the movement direction M corresponds to a rotational direction of the drum, as illustrated in FIGS. 1 and 8. The second preferred embodiment (not illustrated) is when the mask layer is moving on a flatbed table and/or the imaging beams L1, L2, L3 are moving along a flatbed table. The movement direction M in this preferred embodiment corresponds to a longitudinal direction of the flatbed table. The longitudinal direction of the flatbed table is the direction in which the flatbed table presents the greatest dimension in a horizontal plane. A third possibility is to place the mask layer on the inside of a hollow drum, for example placed on an internal surface of the drum, and to perform exposure with a beam generator placed in the centre of the drum. According to one embodiment when the mask layer is placed inside a drum, the mask layer rotates with the drum while the source emitting the imaging beams L1, L2, L3 remains stationary in the drum whilst the first group of Cl pixels and the second group of C2 pixels, and the subsequent group of pixels if present, are imaged. According to another embodiment when the mask layer is placed inside a drum, the mask layer remains stationary while the source emitting the imaging beams L1, L2, L3 rotates inside the drum whilst the first group of Cl pixels and the second group of C2 pixels, and the subsequent group of pixels if present, are imaged. Under this embodiment the source may in addition move in a transverse direction perpendicular to the rotational direction of the drum. The transverse direction is for example the longitudinal direction of the drum. According to yet another embodiment when the mask is placed inside the drum, both the mask layer and the source emitting the imaging beams L1, L2, L3 rotate, the mask layer rotating relative to the imaging beams L1, L2, L3 whilst the first group of Cl pixels and the second group of C2 pixels, and the subsequent group of pixels if present, are imaged. Under this embodiment the source may in addition move in a transverse direction perpendicular to the rotational direction of the drum. The transverse direction is for example the longitudinal direction of the drum.

Where the mask layer moves in the movement direction M relative to the imaging beams L1, L2, L3, in some embodiments the first and the second groups of imaging beams L1, L2, and the subsequent group of imaging beams L3 if present, are arranged next to each other and aligned along a line when the groups of imaging beams L1, L2, L3 are observed perpendicularly to the mask layer. Preferably the line defines an angle with a transverse direction T perpendicular to the movement direction M. The angle is strictly greater than 0 and strictly lower than 90°. The angle compensates for the movement of the mask layer between the first and the second moment in time. Preferably the compensation makes it possible to image pixels aligned in the transverse direction T even if the mask layer moves between the movements when the first group of pixels is imaged and when the second group of pixels is imaged.

According to some embodiments the method comprises moving the imaging beams L1, L2, L3 relative to the mask layer in a transverse direction T perpendicular to the movement direction M. Under these embodiments the imaging beams L1, L2, L3 move relative to the drum over at least (C1+C2) pixels in the transverse direction T. The imaging beams L1, L2, L3 move for example C1+C2 pixels in the transverse direction T when the drum completes one rotation. According to some embodiments, the moving in the transverse direction T perpendicular to the movement direction M is substantially continuous. This is particularly advantageous when the mask layer is rotating on a drum. According to some embodiments the moving in the transverse direction T perpendicular to the movement direction M is in steps. This is particularly advantageous when the mask layer is placed on a flatbed table.

According to some embodiments the method comprises moving the imaging beams L1, L2, L3 relative to the mask layer in a transverse direction T perpendicular to the movement direction M so that the imaging beams L1, L2, L3 move relative to the mask layer over at least (C1+C2) pixels in the transverse direction T. The imaging beams L1, L2, L3 for example move C1+C2 pixels in the transverse directions T when the mask layer moves the entire longitudinal length of the flatbed table.

As shown in FIG. 2 the method further comprises repeating the reading of imaging data, the using of a group of C1 first imaging beams L1 for imaging at a first moment in time, the using of a group of C2 second imaging beams L2 for imaging at a second moment in time, and optionally the using of a subsequent group of imaging beams L3 for imaging at one or more subsequent moments in time, for a next sequence of at least (C1+C2) pixels. According to some embodiments a time period between the reading of imaging data for a first sequence of N*C pixels and for a subsequent sequence of N*C pixels corresponds with N/f1.

### Look-Up Table

According to some embodiments of the present disclosure a look-up table is used to obtain the imaging setting for at least a beam L1, L2, L3 based on the bit sequence of the imaging data corresponding to the plurality of pixels. The look-up table for example comprises a plurality of imaging settings in function of bit sequences.

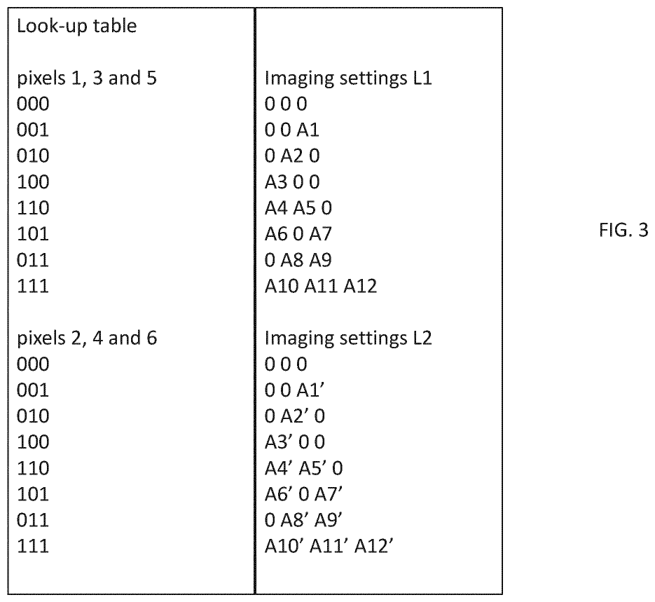

An example of a look-up table according to some embodiments of the present disclosure is shown in FIG. 3.

According to some embodiments, for example the one shown in FIG. 3, the set of bit values comprises for every pixel either ‘1’ if the pixel is an imaging pixel, or ‘0’ if the pixel is a non-imaging pixel. As an alternative, the set of bit values comprises two or more bit values for every pixel. The bit value is ‘2’ if the pixel is an imaging pixel in a solid area, ‘1’ if the pixel is an imaging pixel in a halftone area, or ‘0’ if the pixel is a non-imaging pixel.

According to some embodiments the first and second set of imaging settings comprises C1 imaging settings for the C1 first imaging beams L1 and C2 imaging settings for the C2 second imaging beams L2, respectively. In this way each imaging beam L1, L2, L3 has its own imaging setting. The imaging setting of one beam can be independent of the imaging settings of other beams in a group. To put it differently the imaging setting comprises a plurality of independent values for the plurality imaging beams L1, L2, L3. As an alternative, the imaging setting of one beam can be a function of the imaging settings of other beams in a group. According to some embodiments the imaging setting is modified before the modified imaging setting is used by beams to image pixels. The modified imaging setting for example comprises the modified beam location and/or the modified beam intensity of at least one beam.

According to some embodiments each imaging setting specifies a value which is representative for the size and/or the shape and/or the position of an imaged spot corresponding with an imaging pixel. Preferably the imaging setting defines any one or more of the following parameters:
an intensity value to be used for generating an imaged feature corresponding with an imaging pixel, e.g. an intensity value for controlling a beam used for the imaging,
a time interval to be used for generating an imaged feature corresponding with an imaging pixel, e.g. an on-time value for controlling a beam used for the imaging,
a beam diameter value and/or beam shape value for controlling a beam used for the imaging,
a number of passes used for the imaging,
an indication of an exposure head of a plurality of exposure heads to be used for generating an imaged feature or a group of imaged features corresponding to a pixel or a group of pixels for the imaging.

According to some embodiments the size (from controlling the intensity of the beam) and/or the shape and/or the position of a beam is controlled by controlling the amplitude and/or the frequency and/or the phase of the input wave which is communicated to the beam to control the latter. An acousto-optical system is able to control the parameters of a beam by controlling the amplitude and/or the frequency and/or the phase of the input wave of the beam. An electro-optical system is also able to control the parameters of a beam by controlling the amplitude and/or the frequency and/or the phase.

After the imaging setting is obtained from the look-up table, the method uses a plurality of imaging beams L1, L2, L3 to image substantially simultaneously the plurality of pixels in accordance with the obtained imaging setting.

According to some embodiments the look-up table is determined before the image file is received.

According to some embodiments the sequence of bit values comprising at least two bit values for every pixel. The method comprises obtaining an imaging setting based on the sequence of bit values comprising at least two bit values. The obtaining of the imaging setting can be based on a look-up table as described above, or alternatively not based on any look-up table. The method then uses a plurality of imaging beams L1, L2, L3 for imaging substantially simultaneously the plurality of pixels in accordance with the obtained imaging setting.

According to some embodiments the method comprising detecting at least one solid area and at least one halftone area in the image file. A pixel in the solid area for example receives a value of ‘2’. A pixel in the halftone area for example receives a value of ‘1’. A non-imaging pixel for example receives a value of ‘0’.

According to some embodiments the method comprises converting the at least two bit values into several corresponding one bit values before obtaining an imaging setting based on the one bit values. According to some embodiments the method comprises converting an original string of CI values expressed in a ternary system into a binary string of 2*C1 binary values. The first C1 binary values of the binary string for example is ‘1’ if the pixels correspond to the ones in the solid area (i.e. having an original value of ‘2’). The second C1 binary values of the binary string for example is ‘l’ if the pixels correspond to the imaging pixels (i.e. having an original value of ‘l’ or ‘2’). The same conversion may apply for the original string of C2 values and any potential subsequent string(s) of bit values.

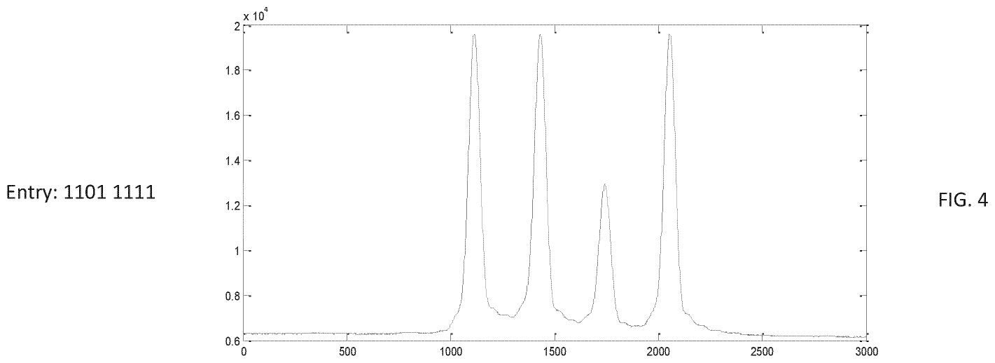

FIGS. 4-7 illustrate four examples of translating a set of two bit values into the instructions of four beam which includes converting the sequence of two bit values into sequences of one bit values. In FIG. 4 the set of two bit values is 2212. This set of two bit values is first converted into two strings of 1 bit values: 1101 and 1111 according to the method described above. Because the second string comprises only ‘1’, all four beams are on. In the first string, the first, the second, and the fourth values are ‘1’; the first, the second, and the fourth beams therefore image pixels in the at least one solid area. The third value in the first string is ‘0’; the third beam thus images a pixel in a halftone area with a reduced beam intensity. This information is used to instruct the beams as can be seen in FIG. 4.

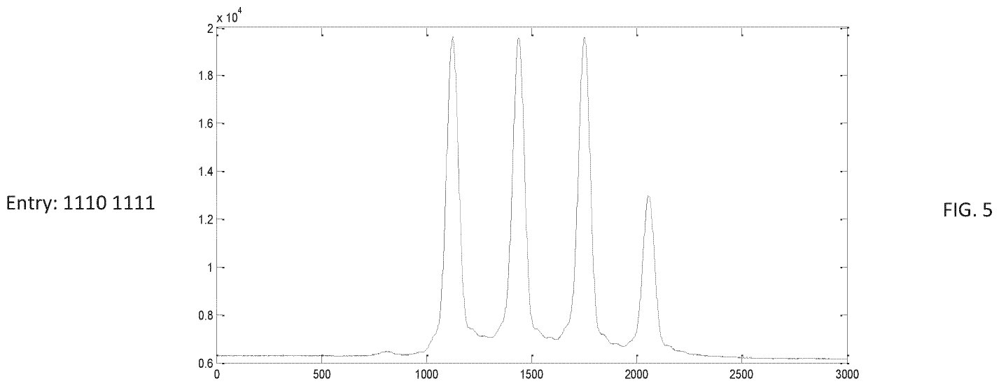

In FIG. 5, the set of two bit values is 2221. This set of two bit values is first converted into two strings one bit values: 1110 and 1111 according to the method described above. Again the second string only comprises ‘1’; therefore all four beams are on. The first, the second, and third values in the first string are ‘1’; these three values therefore correspond to a solid area. The first, the second, and third beams will thus image pixels in the at least one solid area. The fourth value in the first string is ‘0’; the fourth beam therefore image a pixel in a halftone area with a reduced beam intensity.

This information is used to instruct the beams as can be seen in FIG. 5.

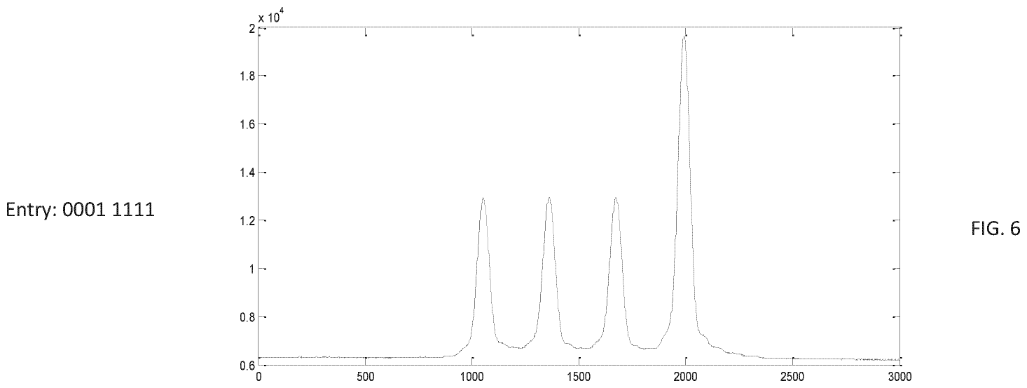

In FIG. 6, the set of two bit values is 1112. This set of two bit values is first converted into two strings of 1 bit values: 0001 and 1111 according to the method described above. Again the second string only comprises ‘1’: all four beams are therefore on. The first, the second, and the third values in the first string is ‘0’; the first, the second, and the third beams therefore image pixels in the at least a halftone area with a reduced beam intensity. The fourth value in the first string is 1: the fourth beam thus images a pixel in a solid area. This information is used to instruct the beams as can be seen the FIG. 6.

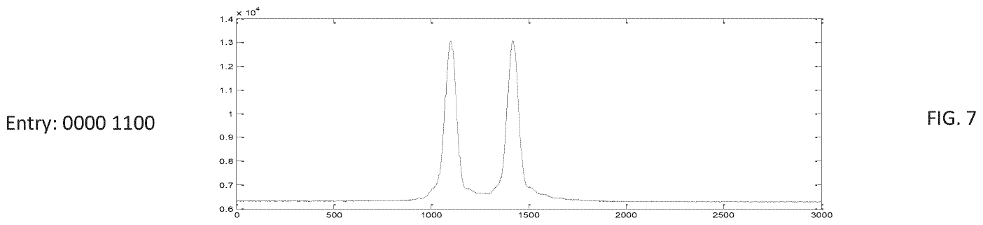

In FIG. 7, the set of two bit values is 1100. This string of two bit values is first converted into two strings of 1 bit values: 0000 and 1100 according to the method above. The third and fourth values in the second string are ‘0’; therefore the third and the fourth beams are off and do not image any pixel. The first and the second values in the second string are ‘1’; the first and second beams are on. The first and second values in the first string are ‘0’; the first and the second beams therefore image pixels in the at least a halftone area with a reduced beam intensity. This information is used to instruct the beams as seen in the FIG. 7.

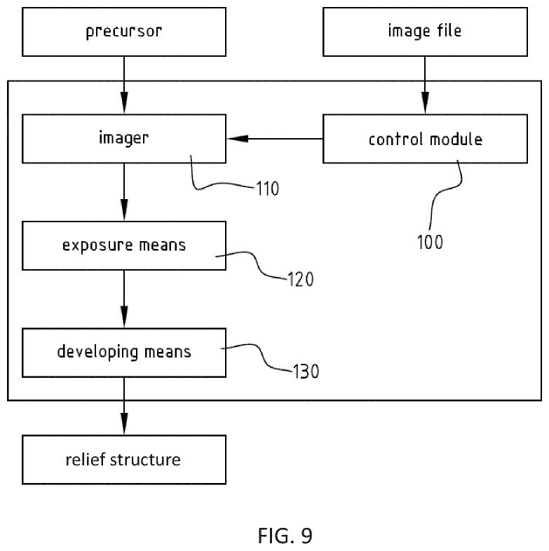

FIG. 9 illustrates a system to a relief structure from a relief precursor. The system comprises a control module 100, an imager 110, an exposure means 120 and a developing means 130. After the mask layer on the precursor is imaged by the imager 110 using the modified image file and/or imaging instructions generated by the control module 100, the precursor is exposed to electromagnetic radiation in the exposure means 120, through the imaged mask layer so that a portion of the photosensitive layer is cured. The electromagnetic radiation may have a wavelength in the range of 200 to 2000 nm, preferably it is ultraviolet (UV) radiation with a wavelength in the range of 200 to 450 nm. The imager 110 used for the imaging step is configured to generate the above discussed beams of electromagnetic radiation capable of modifying the transparency of the mask layer, typically laser beams. The change of transparency may be achieved by ablation, bleaching, color change, refractive index change or combinations thereof. Preferably ablation or bleaching are employed. Preferably, the wavelength of the beams of electromagnetic radiation is in the range of 700 nm to 12,000 nm.

The mask layer can be a separate layer, which is applied to the relief precursor, typically following the removal of a protective layer that may optionally be present, or an integral layer of the precursor, which is in contact with the relief layer or one of the optional layers above the relief layer, and is covered by a protective layer that may possibly be present.

The mask layer can also be a commercially available negative which, for example, can be produced by means of photographic methods based on silver halide chemistry. The mask layer can be a composite layer material in which, by means of image-based exposure, transparent layers are produced in an otherwise non-transparent layer, as described, for example in EP 3 139 210 A1, EP 1 735 664 B1, EP 2 987 030 A1, EP 2 313 270 B1. This can be carried out by ablation of a non-transparent layer on a transparent carrier layer, as described, for example, in U.S. Pat. No. 6,916,596, EP 816 920 B1, or by selective application of a non-transparent layer to a transparent carrier layer, as described in EP 992 846 B1, or written directly onto the relief-forming layer, such as, for example, by printing with a non-transparent ink by means of ink-jet, as described, for example, in EP 1 195 645 A1.

Preferably, the mask layer is an integral layer of the relief precursor and is located in direct contact with the relief-forming layer or a functional layer which is arranged on the relief-forming layer, which is preferably a barrier layer. Furthermore, the integral mask layer can be imaged by ablation and in addition removed with solvents or by heating and adsorbing/absorbing. For example, this layer may be heated and liquefied by means of selective irradiation by means of high-energy electromagnetic radiation, which produces an image-based structured mask, which is used to transfer the structure to the relief precursor. For this purpose, it may be opaque in the UV range and absorb radiation in the visible IR range, which leads to the heating of the layer and the ablation thereof. Following the ablation, the mask layer also represents a relief, typically with lower relief heights, for example in the range from 0.1 to 5 μm.

In an exemplary embodiment, the optical density of the mask layer in the UV range from 330 to 420 nm and/or in the visible IR range from 340 to 660 nm lies in the range from 1 to 5, preferably in the range from 1.5 to 4, particularly preferably in the range from 2 to 4.

The layer thickness of the laser-ablatable mask layer is generally 0.1 to 5 μm. Preferably, the layer thickness is 0.3 to 4 μm, particularly preferably 1 μm to 3 μm. The laser sensitivity of the mask layer (measured as the energy which is needed to ablate a 1 cm² layer) may be between 0.1 and 10 mJ/cm², preferably between 0.3 and 5 mJ/cm², particularly preferably between 0.5 and 5 mJ/cm².

Examples of solidifiable materials that may be used in the photosensitive layer according to some embodiments of the invention are photosensitive compositions, which solidify or cure due to a chemical reaction, which leads to polymerization and/or crosslinking. Such reactions may be radical, cationic or anionic polymerization and crosslinking. Other means for crosslinking are condensation or addition reactions e.g. formation of esters, ethers, urethanes or amides. Such composition may include initiators and/or catalysts, which are triggered by electromagnetic radiation. Such initiators or catalysts can be photo-initiator systems with one or more components that form radicals, acids or bases, which then initiate or catalyze a reaction, which leads to polymerization or crosslinking. The necessary functional groups can be attached to low molecular weight monomers, to oligomers or to polymers. In addition, the composition may comprise additional components such as binders, filler, colorants, stabilizers, tensides, inhibitors, regulators and other additives, which may or may not carry functional groups used in the solidification reaction. Depending on the components used, flexible and/or rigid materials can be obtained after the solidification and post-treatment is finished. The radical reaction may be a radical polymerization, a radical crosslinking reaction or a combination thereof. Preferably, the photosensitive layer is rendered insoluble, solid or not meltable by a radical reaction.

The electromagnetic radiation changes the properties of the exposed parts of the photosensitive layer such that in the following developing means non-exposed portions of the photosensitive layer are removed by the developing means 130 and a relief structure e.g. a printing plate or a sleeve is formed.

Preferably, the removal of the soluble or liquidifiable material is achieved by treatment with liquids (solvents, water or aqueous solutions) or thermal development, wherein the liquefied or softened material is removed.

Treatment with liquids may be performed by spraying the liquid onto the precursor, brushing or scrubbing the precursor in the presence of liquid. The nature of the liquid used is guided by the nature of the precursor employed. If the layer to be removed is soluble, emulsifiable or dispersible in water or aqueous solutions, water or aqueous solutions might be used. If the layer is soluble, emulsifiable or dispersible in organic solvents or mixtures, organic solvents or mixtures may be used. Preferably liquids comprising naphthenic or aromatic petroleum fractions in a mixture with alcohols, such as benzyl alcohol, cyclohexanol, or aliphatic alcohols having 5 to 10 carbon atoms, for example, and also, optionally, further components, such as, for example, alicyclic hydrocarbons, terpenoid hydrocarbons, substituted benzenes such as diisopropylbenzene, esters having 5 to 12 carbon atoms, or glycol ethers, for example.

For thermal development, a thermal development means, wherein the relief precursor is fixed on the rotating drum, may be used. The thermal developing means further comprises assemblies for heating the at least one additional layer and also assemblies for contacting an outer surface of the heated, at least one additional layer with an absorbent material for absorbing material in a molten state. The assemblies for heating may comprise a heatable underlay for the relief precursor and/or IR lamps disposed above the at least one additional layer. The absorbent material may be pressed against the surface of the at least one additional layer by means, for example, of an optionally heatable roll. The absorbent material may be continuously moved over the surface of the flexible plate while the drum is rotating with repeatedly removal of material of the at least one additional layer. In this way molten material is removed whereas non-molten areas remain and form a relief.

The relief precursor may be a precursor for an element selected from the group comprising: a flexographic printing plate, a relief printing plate, a letter press plate, an intaglio plate, a (flexible) printed circuit board, an electronic element, a microfluidic element, a micro reactor, a phoretic cell, a photonic crystal and an optical element, such as a Fresnel lens.

Optionally, the imaging system may further comprise an exposure unit, a washer, a dryer, a light finisher or any other post-exposure unit, a storage unit, a cutting unit, a mounting unit or any combination thereof in order to generate a relief structure as described above.

The relief structure may be treated further and may finally be used as a printing plate. Optionally, the system may further comprises a light finisher or any other post-exposure unit. Optionally, a controller may be provided to control the various units of the imaging system. Optionally, one or more pre-processing modules, such as a raster image processing (RIP) module which converts an image file, such as a pdf file, into a raster image process file, may be provided upstream of the control module 100.

Whilst the principles of the invention have been set out above in connection with specific embodiments, it is to be understood that this description is merely made by way of example and not as a limitation of the scope of protection which is determined by the appended claims.

1-44. (canceled)

45. A control module configured to:
read imaging data for a sequence of at least (C1+C2) pixels, C1 and C2 being integers greater than or equal to 1,
control a plurality of at least (C1+C2) imaging beams arranged next to each other, said plurality of imaging beams comprising a first group of C1 imaging beams (L1) and a second groups of C2 imaging beams (L2);
at a first moment in time, control the first group of C1 first imaging beams (L1) for imaging substantially simultaneously a first group of C1 pixels of said sequence in accordance with the read imaging data,
at a second moment in time, control the second group of C2 second imaging beams (L2) for imaging substantially simultaneously a second group of C2 pixels of said sequence in accordance with the read imaging data,
optionally, at one or more subsequent moments in time, control a subsequent group of imaging beams (L3) for imaging substantially simultaneously a subsequent group of pixels in accordance with the read imaging data, said pixels of said subsequent group being different from the pixels of the first and second group, and
repeat the reading of imaging data, the controlling of the first group of C1 first imaging beams (L1) for imaging at a first moment in time, the controlling of the second group of C2 second imaging beams (L2) for imaging at a second moment in time, and optionally the controlling of a subsequent group of imaging beams (L3) for imaging at one or more subsequent moments in time, for a next sequence of at least (C1+C2) pixels.

46. A control module configured to:
read imaging data for a plurality of pixels;
obtain an imaging setting from a look-up table based on a bit sequence of the imaging data corresponding to the plurality of pixels, the look-up table having a plurality of imaging settings in function of bit sequences; wherein each imaging setting specifies a value which is representative for a size and/or shape of an imaged spot corresponding with an imaging pixel; and
control a plurality of imaging beams (L1, L2, L3) for imaging substantially simultaneously the plurality of pixels in accordance with the obtained imaging setting.

47. A control module configured to:
read imaging data for a plurality of pixels;
obtain an imaging setting based on a sequence of bit values comprising at least two bit values for every pixel of said plurality of pixels; wherein the at least two bit values indicate if the pixel is an imaging pixel in a solid area, an imaging pixel in a halftone area, or a non-imaging pixel; and
control a plurality of imaging beams (L1, L2, L3) for imaging substantially simultaneously the plurality of pixels in accordance with the obtained imaging setting.

48. A system for treating a relief precursor, comprising
an imager configured to image a mask layer; and
the control module according to claim 45 to control the imager.

49. The system of claim 48, comprising any one or more of the following: at least one transport system configured to transport the relief precursor, a storage device, an exposure means configured to expose the relief precursor through the imaged mask layer, a developing means configured to remove at least a part of non-exposed material from the relief precursor, a drying system, a post-exposure device, a cutting device, a mounting station, a heater.

50. A system for treating a relief precursor, comprising:
an imager configured to image a mask layer; and
the control module according to claim 46 to control the imager.

51. The control module of claim 45, wherein C1 and C2 are integers greater than or equal to 2, and wherein the control module is configured to select said C1 pixels of the first group such that at least two pixels of the first group are separated by at least one pixel not belonging to the first group and to select said C2 pixels of the second group such that at least two pixels of the second group are separated by at least one pixel not belonging to the second group.

52. The control module of claim 51, wherein C1=C2=C, and wherein each sequence contains N*C pixels, N being an integer greater than or equal to 2.

53. The control module of claim 45, further comprising a clock having a first frequency f1, wherein a time period between subsequent moments in time corresponds to 1/f1, and wherein reading imaging data of the at least (C1+C2) pixels comprises reading imaging data of the C1 pixels and then, after an interval of 1/f1, reading imaging data of the C2 pixels.

54. The control module of claim 52, further comprising a clock having a first frequency f1, wherein a time period between subsequent moments in time corresponds to 1/f1, and wherein reading imaging data of the at least (C1+C2) pixels comprises reading imaging data of the C1 pixels and then, after an interval of 1/f1, reading imaging data of the C2 pixels;
wherein a time period between the reading of imaging data for a first sequence and for a subsequent sequence corresponds with N/f1.

55. The control module of claim 52, wherein the C pixels in the n-th group, n being an integer, 1≤n≤N, comprise the n-th pixel, the (n+N)-th pixel, the (n+2*N)-th pixel, etc. of the sequence of N*C pixels and/or wherein the sequence corresponds to a single row in the imaging data.

56. The control module of claim 52, wherein the sequence corresponds to parts of different rows in the imaging data, preferably the C pixels in the n-th group comprises the n-th pixel of the m-th row, the (n+N)-th pixel of the (m+1)-th row, the (n+2*N)-th pixel of the (m+2)-th row, . . . , 1≤m≤N with m being an integer.

57. The control module of claim 45, wherein the control is configured to obtain a first set of imaging settings for said first group of C1 pixels and to control the imaging beams to image substantially simultaneously the first group of C1 pixels in accordance with said first set of imaging settings, and to obtain a second set of imaging settings for said second group of C2 pixels and to control the imaging beams to image substantially simultaneously the second group of C2 pixels in accordance with said second set of imaging settings, wherein for each group of pixels the set of imaging settings is different.

58. The control module of claim 45, wherein the control module is configured to perform controlling such that all the pixels in the first group are separated by at least one pixel not belonging to the first group and wherein all the pixels in the second group are separated by at least one pixel not belonging to the second group.

59. The system of claim 48, further comprising a movement means configured to move the mask layer in a movement direction (M) relative to the imaging beams (L1, L2, L3) whilst the first group of C1 pixels and the second group of C2 pixels, and the subsequent group of pixels if present, are imaged.

60. The system of claim 59, comprising a rotatable drum for supporting the mask whilst the first group of C1 pixels and the second group of C2 pixels, and the subsequent group of pixels if present, are imaged, and wherein the movement direction (M) corresponds to a rotational direction of the drum or comprising a flatbed table for supporting the mask layer whilst the first group of C1 pixels and the second group of C2 pixels, and the subsequent group of pixels if present, are imaged, and wherein the movement direction (M) corresponds to a longitudinal direction of the flatbed table.

61. The system of claim 59, wherein the movement means is configured to move the imaging beams (L1, L2, L3) relative to the mask layer in a transverse direction (T) perpendicular to the movement direction so that the imaging beams (L1, L2, L3) move relative to the mask layer over at least (C1+C2) pixels in the transverse direction, wherein preferably the moving in the transverse direction (T) perpendicular to the movement direction (M) is substantially continuous.

62. The control module of claim 46, wherein the read bit sequence comprises for every pixel of said plurality of pixels a ‘1’ if the pixel is an imaging pixel, or a ‘0’ if the pixel is a non-imaging pixel and/or wherein the bit sequence comprises at least two bit values for every pixel of said plurality of pixels.

63. The control module of claim 46, wherein the imaging setting comprises a plurality of separate independent values for the plurality imaging beams (L1, L2, L3).

64. The control module of claim 46, wherein the imaging setting defines any one or more of the following parameters:
an intensity value to be used for generating an imaged feature corresponding with an imaging pixel, e.g. an intensity value for controlling a beam used for the imaging,
a time interval to be used for generating an imaged feature corresponding with an imaging pixel, e.g. an on-time value for controlling a beam used for the imaging,
a beam diameter value and/or beam shape value for controlling a beam used for the imaging,
a number of passes used for the imaging, and
an indication of an exposure head of a plurality of exposure heads to be used for generating an imaged feature or a group of imaged features corresponding to a pixel or a group of pixels for the imaging.
